(19) United States
(12) Patent Application Publication
(10) Pub. No.: US 2026/0140454 A1
(43) Pub. Date: May 21, 2026

(54) OPTICAL SYSTEM FOR METROLOGY

(71) Applicant: ASML NETHERLANDS B.V., Veldhoven (NL)

(72) Inventor: Douglas C. CAPPELLI, Norwalk, CT (US)

(73) Assignee: ASML NETHERLANDS B.V., Veldhoven (NL)

(21) Appl. No.: 19/123,378

(22) PCT Filed: Oct. 23, 2023
(86) PCT No.: PCT/EP2023/079452

§ 371 Date: Apr. 22, 2025

Related U.S. Application Data
(60) Provisional application No. 63/425,249, filed on Nov. 14, 2022.

(51) Int. Cl. G03F 7/00

(52) U.S. Cl. CPC G03F 7/706851; G03F 7/70633; G03F 7/706845; G03F 7/706849

(57) ABSTRACT

An optical system including a double quad mirror. The optical system is configured to reflect two quadrants of an incident radiation beam approaching from either side of the mirror, while allowing the opposite two quadrants to transmit incident radiation. The optical system has a body with at least one transmissive surface and at least one reflective surface for radiation incident on different sides of the body. The at least one reflective surface on the body is adjacent to a recess within the body that creates an air gap for total internal reflection of radiation incident on the reflective surface toward a first target or toward a sensor. The at least one transmissive surface on the body is configured to transmit incident radiation through the body toward a second target or toward the sensor.

### CROSS-REFERENCE TO RELATED APPLICATIONS

This application claims priority of U.S. application 63/425,249 which was filed on 14 Nov. 2022, and which is incorporated herein in its entirety by reference.

### TECHNICAL FIELD

This description relates to an optical system for a metrology.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, deposition, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

To overcome difficulties processing such small devices, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

An optical system comprising a double quad mirror is described. Two quadrants of the quad mirror are configured to reflect two corresponding quadrants of an incident radiation beam approaching from either side of the mirror, while two opposite quadrants of the quad mirror are configured to transmit incident radiation. Reflective surfaces on a body of the optical system are adjacent to recesses within the body that create an air gaps for total internal reflection of radiation incident on the reflective surfaces. This air gap configuration enables the use of total internal reflections in a dual sided quad mirror, without creating a risk of “parallel plate ghosts”, for example, among other advantages.

According to an embodiment, the optical system comprises a body having at least one transmissive surface and at least one reflective surface for radiation incident on different sides of the body. The at least one reflective surface on the body is adjacent to a recess within the body that creates an air gap for total internal reflection of radiation incident on the reflective surface toward a first target or toward a sensor. The at least one transmissive surface on the body is configured to transmit incident radiation through the body toward a second target or toward the sensor.

In some embodiments, the at least one reflective surface comprises first and second reflective surfaces arranged in opposite quadrants of a first internal surface of the body, and the at least one transmissive surface comprises first and second transmissive surfaces arranged in two remaining quadrants of the first internal surface.

In some embodiments, the first and second reflective surfaces are configured to reflect two quadrants of incident radiation from a radiation source toward the first target, and the first and second transmissive surfaces are configured to (1) transmit the incident radiation from two remaining quadrants of radiation from the radiation source through the body toward the second target, and (2) transmit radiation reflected from the first target toward the sensor.

In some embodiments, four additional reflective surfaces are arranged in alternating quadrants of a second internal surface of the body, with four additional transmissive surfaces arranged in four remaining quadrants of the second internal surface.

In some embodiments, the four additional reflective surfaces are configured to reflect radiation reflected from the second target toward the sensor, and the four additional transmissive surfaces are configured to (3) transmit the incident radiation from the two remaining quadrants of radiation from the radiation source through the body toward the second target, and (4) transmit radiation reflected from the first target toward the sensor.

In some embodiments, the body comprises three separate portions coupled together to form a unitary structure.

In some embodiments, the three portions comprise a first portion formed from a transparent material. The first portion is configured to transmit the incident radiation from the radiation source and the reflected radiation from the first target to the first internal surface of the body.

In some embodiments, the three portions further comprise a third portion formed from the transparent material. The third portion is configured to transmit the incident radiation from the radiation source to the second target, and transmit the reflected radiation from the second target to the second internal surface of the body.

In some embodiments, the three portions further comprise a second portion positioned between the first portion and the third portion. The second portion comprises the first and second internal surfaces on opposite sides of the second portion.

In some embodiments, the first and second reflective surfaces and the four additional reflective surfaces are formed by etching recesses in the first and second internal surfaces respectively, to form air gaps in the body when the three separate portions are coupled together.

In some embodiments, the second portion has a trapezoidal prism shape.

In some embodiments, the optical system comprises a double quad mirror.

In some embodiments, the body comprises a transmissive optic cube.

In some embodiments, the optical systems forms a portion of an alignment and/or an overlay metrology system. In some embodiments, the alignment and/or overlay metrology system comprises a radiation source configured to generate the incident radiation, and the sensor. The sensor is configured to receive radiation from the first and/or second targets and generate a detection signal.

According to another embodiment, there is provided an alignment and/or overlay metrology system. The system comprises a radiation source configured to generate incident radiation; a sensor configured to generate a detection signal; and a body having at least one transmissive surface and at least one reflective surface for radiation incident on different sides of the body. The at least one reflective surface on the body is adjacent to a recess within the body that creates an air gap for total internal reflection of radiation incident on the reflective surface toward a first target or toward a sensor. The at least one transmissive surface on the body is configured to transmit incident radiation through the body toward a second target or toward the sensor.

In some embodiments, the at least one reflective surface comprises first and second reflective surfaces arranged in opposite quadrants of a first internal surface of the body. The at least one transmissive surface comprises first and second transmissive surfaces arranged in two remaining quadrants of the first internal surface.

In some embodiments, the first and second reflective surfaces are configured to reflect two quadrants of incident radiation from a radiation source toward the first target, and the first and second transmissive surfaces are configured to (1) transmit the incident radiation from two remaining quadrants of radiation from the radiation source through the body toward the second target, and (2) transmit radiation reflected from the first target toward the sensor.

In some embodiments, four additional reflective surfaces are arranged in alternating quadrants of a second internal surface of the body, with four additional transmissive surfaces arranged in four remaining quadrants of the second internal surface.

In some embodiments, the four additional reflective surfaces are configured to reflect radiation reflected from the second target toward the sensor, and the four additional transmissive surfaces are configured to (3) transmit the incident radiation from the two remaining quadrants of radiation from the radiation source through the body toward the second target, and (4) transmit radiation reflected from the first target toward the sensor.

In some embodiments, the body comprises three separate portions coupled together to form a unitary structure. The three portions comprise a first portion formed from a transparent material. The first portion is configured to transmit the incident radiation from the radiation source and the reflected radiation from the first target to the first internal surface of the body. The three portions comprise a third portion formed from the transparent material. The third portion is configured to transmit the incident radiation from the radiation source to the second target, and transmit the reflected radiation from the second target to the second internal surface of the body. The three portions comprise a second portion positioned between the first portion and the third portion. The second portion comprises the first and second internal surfaces on opposite sides of the second portion.

In some embodiments, the first and second reflective surfaces and the four additional reflective surfaces are formed by etching recesses in the first and second internal surfaces respectively, to form air gaps in the body when the three separate portions are coupled together.

In some embodiments, the alignment and/or overlay detection metrology system is configured for a semiconductor wafer, and is used in a semiconductor manufacturing process.

In some embodiments, the first and second targets comprise different areas of a same target structure on a wafer, two different target structures on the wafer, or two different target structures on two different wafers.

In some embodiments, the transmissive and reflective surfaces are configured to reduce or eliminate an offset of an incident radiation beam, and/or decrease a risk of parallel plate ghosts compared to prior alignment and/or overlay systems.

According to other embodiments, there are provided one or more methods comprising one or more of the operations described above.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates a metrology system associated with semiconductor manufacturing that has a double quad mirror, according to an embodiment.

FIG. 7 illustrates a more detailed example of the double quad mirror shown in FIG. 6, according to an embodiment.

FIG. 8 illustrates how the present system eliminates incident radiation beam offset and lowers a risk of parallel plate ghosts, among other advantages, in exchange for a small pupil defocus relative to the reflective surfaces of the present system, according to an embodiment.

FIG. 9 illustrates an alternative form of the double quad mirror, according to an embodiment.

FIG. 10 illustrates another alternative form of the double quad mirror, according to an embodiment.

FIG. 11 illustrates yet another alternative form of the double quad mirror, according to an embodiment.

FIG. 12 illustrates a metrology method, according to an embodiment.

FIG. 13 is a block diagram of an example computer system, according to an embodiment.

### DETAILED DESCRIPTION

Metrology systems associated with semiconductor manufacturing have a need for an optical component comprising “double sided quad mirror”. A “double sided quad mirror,” and/or “double quad mirror,” as described herein may be phrases used to generally describe any optical component where two quadrants of the optical component are configured to reflect two corresponding quadrants of an incident radiation beam approaching from either side of the optical component, while two opposite quadrants of the optical component are configured to transmit incident radiation. These metrology systems may be used to image and/or otherwise inspect two targets (e.g., on the same substrate such as a semiconductor wafer, or on different substrates) simultaneously. Several options for such an optical component have been proposed, but have not adequately met the requirements of semiconductor metrology systems. For example, one option is a beam splitter cube with a beam splitting surface that has two quadrants mirror coated and two quadrants with a transparent coating. A challenge associated with this and other similar concepts is ensuring that the reflective quadrants have 0% transmission of incident radiation. If any radiation is transmitted through a reflective quadrant, issues related to light from the quadrants that are being illuminated leaking into the opposing quadrants, which are intended to be un-illuminated, may arise. For example, a wafer with two quadrants may be illuminated. The wafer may return most of the light in the same two quadrants while scattering a small amount into the other two un-illuminated quadrants, and only the scattered light may be isolated for measurement (the term for this being “dark field imaging”). Any reflection from transparent quadrants or transmission from the reflective quadrants may allow illumination light into the un-illuminated quadrants, which will reflect off the wafer and overlap the scattered light that was intended to be measured, potentially drowning the scattered light out. In addition, parallel plate ghosts may result from low-percentage reflections off of a transparent area of two parallel planes if the planes are close enough together to allow some of the light that reflects off of each plane once to remain within the beam (as described below). Parallel plate ghosts may be caused by reflections from transparent quadrants or transmission in reflective quadrants in combination with a pair of parallel surfaces that are relatively close together. Another challenge is accounting for the thickness of the mirror coatings when bonding halves of the cube together (the transparent quadrants would normally be uncoated, but this would result in essentially a “stepped” surface with the surface of the mirror coating sitting higher than the uncoated areas, creating challenges regarding bonding to this surface).

Advantageously, the optical system described below comprises a double quad mirror, but does not carry the risks associated with prior systems. The optical system described below has a body with at least one transmissive surface and at least one reflective surface for radiation incident on different sides of the body. The at least one reflective surface on the body is adjacent to a recess within the body that creates an air gap for total internal reflection of radiation incident on the reflective surface toward a first target or toward a sensor. The at least one transmissive surface on the body is configured to transmit incident radiation through the body toward a second target or toward the sensor. The reflective surface and the air gap facilitate the total internal reflections and form a dual sided quad mirror, without creating a risk of “parallel plate ghosts” (e.g., a secondary, non-desired image of a target caused by radiation that has passed through a reflective quadrant bouncing off some other surface of the cube), a risk associated with an uneven bonding surface, and/or other risks associated with prior systems.

By way of a brief introduction, the description below relates to semiconductor device manufacturing and patterning processes. The following paragraphs also describe several components of systems and/or methods for semiconductor device metrology. These systems and methods may be used for measuring overlay, alignment, etc., in a semiconductor device manufacturing process, for example, or for other operations.

Although specific reference may be made in this text to the measurement of overlay, alignment, or other parameters, and the manufacture of integrated circuits (ICs) for semiconductor devices, it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device.

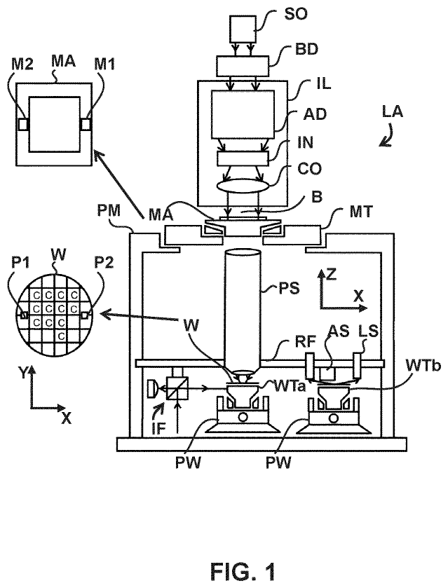

FIG. 1 schematically depicts an embodiment of a lithographic apparatus LA. The apparatus comprises an illumination system (illuminator) IL configured to condition a radiation beam B (e.g.

UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as o-outer and o-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system.”

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be conducted on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

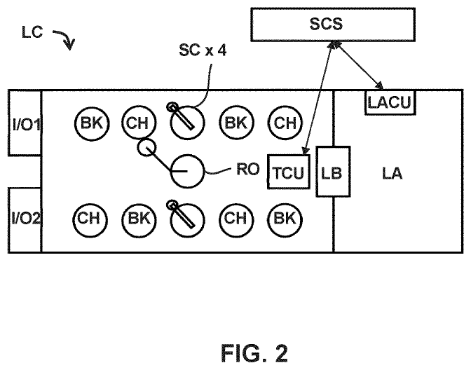

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of overlay, alignment, etc. For example, overlay and/or alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

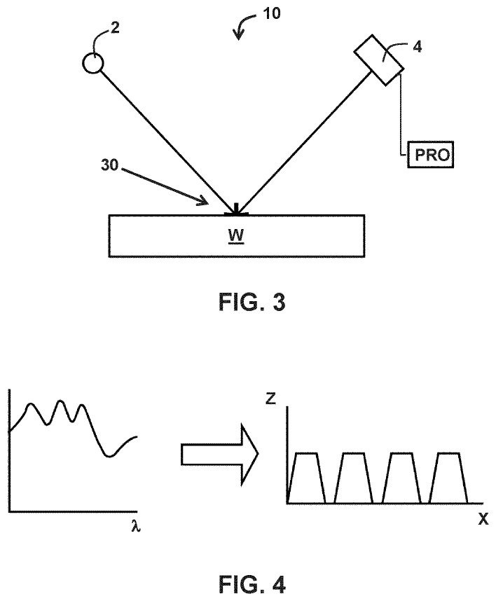

FIG. 3 depicts an example metrology (inspection) system 10 that may be used to detect overlay, alignment, and/or perform other metrology operations. It comprises a radiation or illumination source 2 which projects or otherwise irradiates radiation onto a substrate W (e.g., which may typically include a metrology mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying metrology data indicative of properties of the reflected radiation. From this data, the structure or profile giving rise to the detected spectrum may be reconstructed by one or more processors PRO, a generalized example of which is shown in FIG. 4, or by other operations.

As in the lithographic apparatus LA in FIG. 1, one or more substrate tables (not shown in FIG. 3 or 4) may be provided to hold the substrate W during measurement operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target (portion) 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate overlay for a layer of a semiconductor device. The measured data from target 30 may be used (e.g., by the one or more processors PRO and/or other processors) for determining one or more semiconductor device manufacturing process parameters based the overlay, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

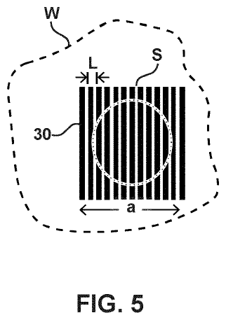

FIG. 5 illustrates a plan view of a typical target (e.g., metrology mark) 30, and the extent of a typical radiation illumination spot S in the system of FIG. 4. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

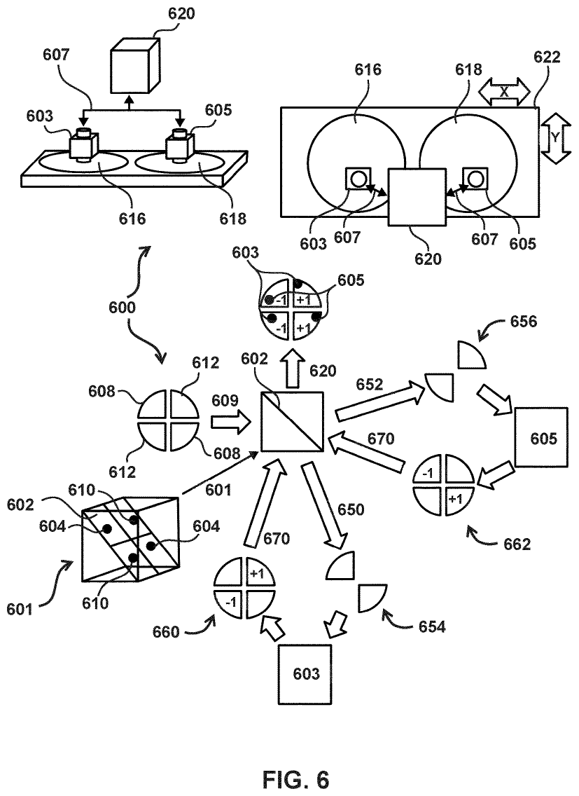

FIG. 6 illustrates a metrology system 600 associated with semiconductor manufacturing. FIG. 6 and system 600 show a more detailed version of system 10 shown in FIG. 3. In some embodiments, system 600 may form, or form a portion of, system 10 described above with respect to FIG. 3. System 600 may illustrate various subsystems of system 10, for example. In some embodiments, one or more components of system 600 may be similar to and/or the same as one or more components of system 10. In some embodiments, one or more components of system 600 may replace, be used with, and/or otherwise augment one or more components of system 10.

Metrology system 600 has two objectives 603 and 605 configured for directing radiation 607 to or from one or more metrology targets, such as one or more diffraction grating targets in substrates 616, 618 such as semiconductor wafers. Radiation 607 may have a target wavelength and/or wavelength range, a target intensity, and/or other characteristics. The target wavelength and/or wavelength range, the target intensity, etc., may be entered and/or selected by a user, determined by the system (e.g., system 600 or system 10 shown in FIG. 3) based on previous measurements, and/or determined in other ways. In some embodiments, the radiation comprises light and/or other radiation. In some embodiments, the light comprises visible light, infrared light, near infrared light, and/or other light. In some embodiments, the radiation may be any radiation appropriate for interferometry.

The substrates 616 and 618 are shown on a moveable substrate table 622 (e.g., WTa or WTb as described above). System 600 may be used to image and/or otherwise inspect two targets (e.g., on the same substrate 616 or 618 such as a semiconductor wafer, or on different substrates 616, 618 as shown in FIG. 6) simultaneously. Radiation 607 may be used by a sensor 620 (e.g., similar to and/or the same as detector 4 and/or processor PRO shown in FIG. 3) to obtain images of the metrology targets, and/or for other uses. A target (e.g., target 30 described above) may comprise one or more metrology marks, such as diffraction grating targets, formed in a substrate 616, 618 such as a semiconductor wafer, for example.

System 600 includes a sub-system 601 comprising a double quad mirror 602 (as described above, “double quad mirror” is used generally and is not strictly limited to a component with double sided mirrors). Quad mirror 602 is configured such that two quadrants 604 of quad mirror 602 are configured to reflect two corresponding quadrants 608 of an incident radiation beam 609 approaching from either side of mirror 602 (beam 609 is shown approaching from a radiation source in this example), while two opposite quadrants 610 of quad mirror 602 are configured to transmit incident radiation (e.g., from opposite quadrants 612).

Quad mirror 602 has two reflective and two transmissive quadrants (e.g., 602 and 604 respectively), which split four quadrants (608 and 612) of radiation 607 into two beams 650 and 652, each with two quadrant illumination 654 and 656. As shown in FIG. 6, +/− first order radiation 660, 662 from each objective 603 and 605 is sent 670 to sensor 620 along a detection path by double quad mirror 602. Quad mirror 602 allows 0th order radiation to travel back up an illumination path.

System 600 enhances throughput compared to prior systems because multiple targets can be imaged simultaneously. System 600 also still allows different illumination patterns for various metrology applications. Other advantages are contemplated.

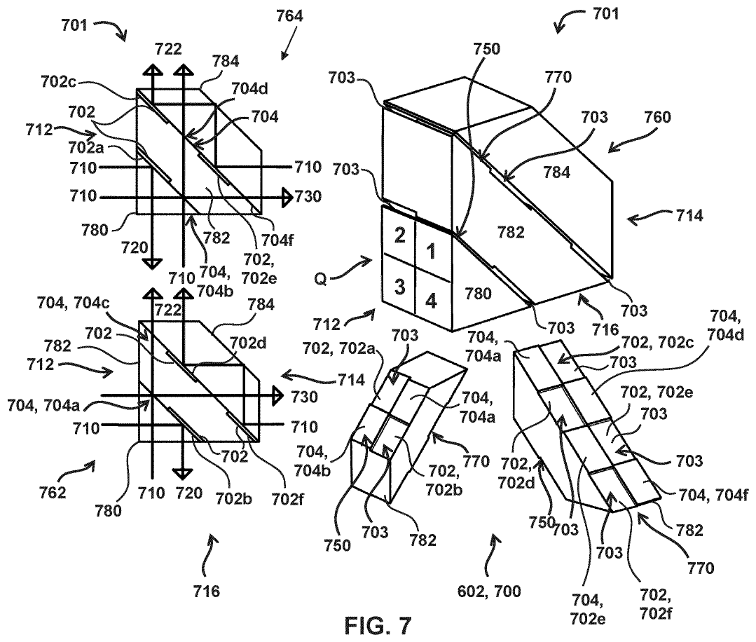

FIG. 7 illustrates a more detailed example of double quad mirror 602 and sub-system 601 shown in FIG. 6. In FIG. 7, double quad mirror 602 is formed by system 700. System 700 functions as a double quad mirror. System 700 comprises a body 701 and/or other components. Body 701 comprises a transmissive optic cube, for example, and/or other structures. Body 701 comprises at least one transmissive surface 704 and at least one reflective surface 702 for radiation 710 incident on different sides 712, 714, 716 of body 701, and/or other components. The at least one reflective surface 702 on body 701 is adjacent to a recess 703 within body 701 that creates an air gap for total internal reflection of radiation 710 incident on the reflective surface 702 toward 720 a first target or toward 722 a sensor (see FIG. 6). The at least one transmissive surface 704 on body 701 is configured to transmit incident radiation 710 through body 701 toward 730 a second target or toward 722 the sensor.

In some embodiments, the at least one reflective surface 702 comprises first and second reflective surfaces 702a and 702b arranged in opposite quadrants of a first internal surface 750 of body 701. The at least one transmissive surface 704 comprises first and second transmissive surfaces 704a and 704b arranged in two remaining quadrants of first internal surface 750. The first and second reflective surfaces 702a and 702b are configured to reflect two quadrants Q of incident radiation 710 from a radiation source toward 720 the first target. (See perspective view 760, and cross sectional views 762 (taken through body 701 at a location corresponding to quadrants 1 and 4) and 764 (taken through body 701 at a location corresponding to quadrants 2 and 3) of body 701.) First and second transmissive surfaces 704a and 704b are configured to transmit the incident radiation from two remaining quadrants of radiation from the radiation source through the body toward 730 the second target, and transmit radiation reflected from the first target toward 722 the sensor.

In some embodiments, four additional reflective surfaces 702c, 702d, 702e, and 702f are arranged in alternating quadrants of a second internal surface 770 of body 701, with four additional transmissive surfaces 704c, 704d, 704e, and 704f arranged in four remaining quadrants of second internal surface 770. The four additional reflective surfaces 702c, 702d, 702e, and 702f are configured to reflect radiation reflected from the second target toward 722 the sensor. The four additional transmissive surfaces 704c, 704d, 704e, and 704f are configured to transmit the incident radiation from the two remaining quadrants of radiation from the radiation source through the body toward 730 the second target, and transmit radiation reflected from the first target toward 722 the sensor.

In some embodiments, body 701 comprises two or more separate portions configured to be coupled together to form body 701. In some embodiments, body 701 comprises three separate portions 780, 782, and 784 coupled together to form a unitary structure. For example, body 701 may have a prism design, with three pieces (portions 780-784) and two hypotenuses (e.g., surfaces 750 and 770), one that is reflective from one direction, and one that is reflective from the another (e.g., as shown in FIG. 7). In some embodiments, the three portions comprise a first portion 780 formed from a transparent material and/or other materials. The transparent material may be glass, for example, and/or other materials. First portion 780 is configured to transmit the incident radiation 710 from the radiation source and the reflected radiation from the first target to the first internal surface 750 of body 701. Third portion 784 may also be formed from the transparent material (e.g., glass) and/or other materials. Third portion 784 is configured to transmit the incident radiation 710 from the radiation source to the second target, and transmit the reflected radiation from the second target to the second internal surface 770 of body 701. The three portions also comprise a second portion 782 positioned between first portion 780 and third portion 784. Second portion 782 comprises first and second internal surfaces 750 and 770 on opposite sides of second portion 782. Second portion 782 may also be made of glass and/or other materials, for example.

In some embodiments, second portion 782 has a trapezoidal prism shape. In some embodiments, first and second reflective surfaces and the four additional reflective surfaces (e.g., 702a-702f) are formed by etching recesses 703 in the first and second internal surfaces 750 and 770 respectively, to form air gaps in body 701 when the three separate portions 780-784 are coupled together. In some embodiments, second portion 782 is coupled to first and/or third portions 780 and 784 by optical contacting (e.g., a method of bonding glass or other materials with surfaces so flat that intermolecular forces hold the pieces together), glue and/or other adhesives (e.g., which are transparent for wavelengths of interest), clamps, clips, and/or other coupling mechanisms. In some embodiments, an angle of inclination of the surfaces 750 and 770 comprises an angle configured to ensure total internal reflection. This may include various possible angles (provided any other prism adjustments are made, based on the angle of inclination, to ensure total internal reflection).

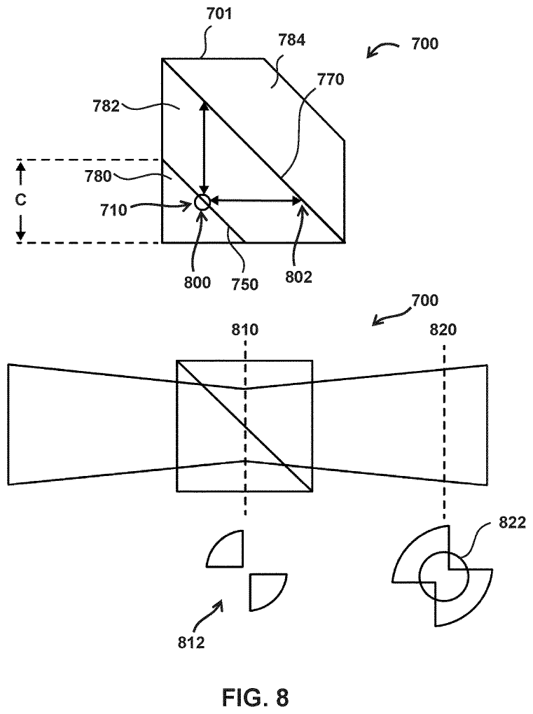

FIG. 8 illustrates how system 700 eliminates potential incident radiation 710 beam offset and lowers a risk of parallel plate ghosts, among other advantages, in exchange for a small pupil defocus relative to the reflective surfaces (see FIG. 7) of system 700. A parallel plate ghost may be a secondary, non-desired image of a target caused by radiation that has passed through a reflective quadrant bouncing off some other surface of body 701. For example, body 701 comprises second portion 782, which includes first and second internal surfaces 750 and 770 on opposite sides of second portion 782. Second portion 782 is configured with a thickness large enough to reduce or eliminate parallel plate ghosts, for example.

With this structure, if a pupil is in focus at a location 800 on surface 750, it cannot be in focus at a second location 802 on surface 770. However, because the pupil cannot be in focus on both surfaces at the same time, there is a risk of radiation quadrant mixing, depending on the exact focus location. FIG. 8 illustrates a first focus location 810, with separate radiation quadrants 812, and a second focus location 820, with resulting mixed quadrants 822. It is possible to limit the defocus to approximately C/n, where C is a incident radiation facing end dimension of portion 780 as shown in FIG. 8, n is a refractive index of glass (or another transparent material used to form body 701).

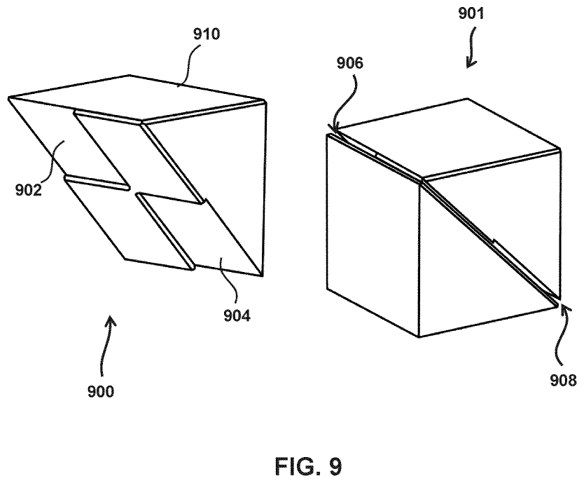

System 700 may take alternate forms. One such alternate form is illustrated in FIG. 9 as system 900. System 900 comprises a cube shaped prism 901. System 900 is configured with reflective surfaces 902 and 904 adjacent to air gaps 906 and 908 formed by removing material from an opposing prism piece 910, thus facilitating total internal reflection of incident radiation in the air-gapped area. A challenge regarding this approach associated with double sided quad mirrors is making reflective surfaces 902 and 904 reflective from both sides. For example, this may require polishing (or otherwise making reflective) the bottoms (or back sides) of opposing prism piece 910 reflective surfaces 902 and 904. This may be difficult because these bottoms or back sides are encapsulated with the body of opposing prism piece 910. However, it may be possible to use techniques associated with additive manufacturing, as one example, to selectively increase the reflectivity of selected portions (e.g., the backsides of surfaces 902 and 904) of opposing prism piece 910. In some embodiments, these pieces may be coupled by optical contacting (e.g., as described above), glue and/or other adhesives (e.g., which are transparent for wavelengths of interest), clamps, clips, and/or other coupling mechanisms.

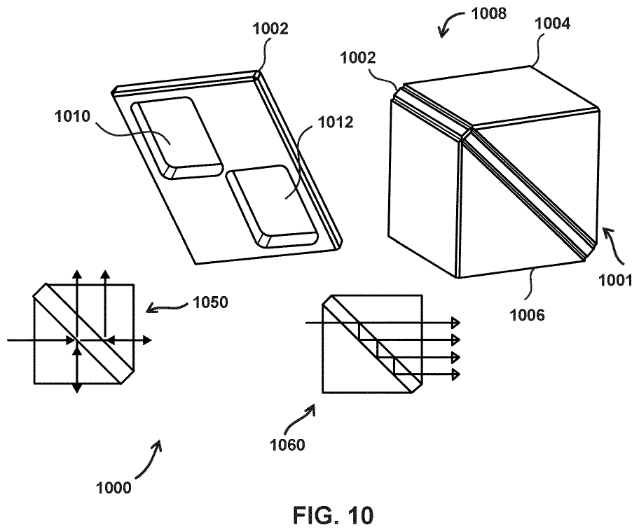

Another alternate form of system 700 (FIG. 7) is illustrated in FIG. 10 as system 1000. System 1000 again comprises a cube shaped prism 1001. System 1000 comprises a spacer plate 1002 positioned between opposing portions 1004 and 1006 of a body 1008. Spacer plate 1002 is configured to create air gaps 1010 and 1012 for total internal reflection, with high quality reflective surfaces located on internal surfaces of portions 1004 and 1006 adjacent to air gaps 1010 and 1012 when portions 1004 and 1006 are coupled with plate 1002 on either side of the air gaps. These high quality reflective surfaces may be created by polishing and/or other techniques. In some embodiments, there may be an offset 1050 between retuned radiation beams from different objectives (see FIG. 6). This has the potential to create unwanted parallel plate ghosts 1060 caused by a low percentage reflection of the nominally transparent quadrants at an interface between spacer plate 1002 and opposing portions 1004 and 1006. In some embodiments, these pieces may be coupled by optical contacting (e.g., as described above), glue and/or other adhesives (e.g., which are transparent for wavelengths of interest), clamps, clips, and/or other coupling mechanisms.

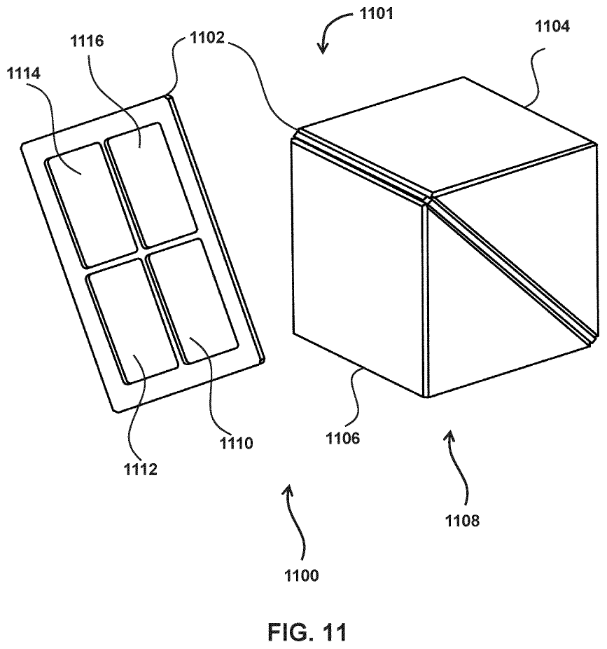

Yet another alternate form is illustrated in FIG. 11 as system 1100. System 1100 again comprises a cube shaped prism 1101. System 1100 comprises a spacer plate 1102 positioned between opposing portions 1104 and 1106 of a body 1108. Spacer plate 1102 is configured to create total internal reflection air gaps 1110, 1112, 1114, and 1116. Air gaps 1112 and 1114 (in this example) may be selectively filled with glue and/or some other substance to eliminate total internal reflection in transmitting quadrants. Advantageously, spacer plate 1102 need not be transparent (e.g., so that a glass part may be replaced with a metal part, which may be easier to obtain). However, it is possible that birefringence from a glue layer may be produced.

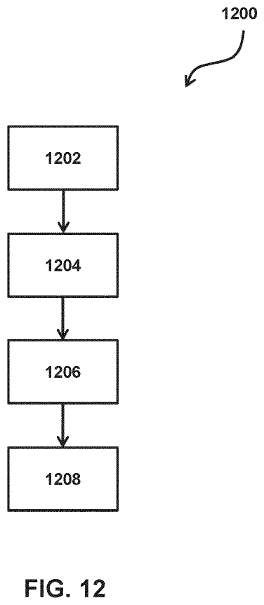

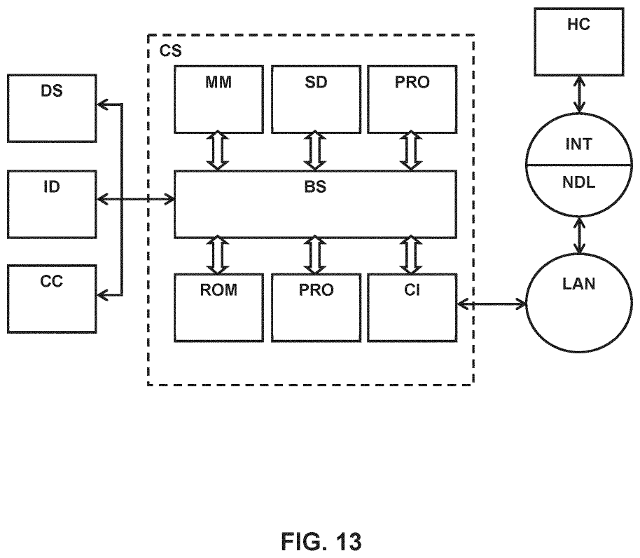

FIG. 12 illustrates a metrology method 1200. In some embodiments, method 1200 is performed as part of an overlay and/or alignment sensing operation in a semiconductor device manufacturing process, for example. In some embodiments, one or more operations of method 1200 may be implemented in or by system 600 illustrated in FIG. 6, system 700 shown in FIG. 7, system 10 illustrated in FIG. 3, a computer system (e.g., as illustrated in FIG. 13 and described below), and/or in or by other systems, for example. In some embodiments, method 1200 comprises generating (operation 1202) incident radiation with a radiation source, generating (operation 1204) a detection signal with a sensor, forming (operation 1206) at least one reflective surface on a body adjacent to a recess within the body to create an air gap for total internal reflection of incident radiation on the reflective surface toward a first target or toward the sensor, and transmitting (operation 1208), with at least one transmissive surface formed on the body, the incident radiation through the body toward a second target or toward the sensor.

The operations of method 1200 are intended to be illustrative. In some embodiments, method 1200 may be accomplished with one or more additional operations not described, and/or without one or more of the operations discussed. For example, in some embodiments, method 1200 may include an additional operation comprising determining an adjustment for a semiconductor device manufacturing process. Additionally, the order in which the operations of method 1200 are illustrated in FIG. 12 and described herein is not intended to be limiting.

In some embodiments, one or more portions of method 1200 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1200 in response to instructions stored electronically on an electronic storage medium. The one or more processing devices may include one or more devices configured through hardware, firmware, and/or software to be specifically designed for execution of one or more of the operations of method 1200 (e.g., see discussion related to FIG. 13 below).

At operation 1202, incident radiation is generated with a radiation source. In some embodiments, the radiation source is the same as or similar to source 2 shown in FIG. 3 and described above. In some embodiments, the radiation may be light and/or other radiation directed by the radiation source onto multiple targes, a single target, sub-portions (e.g., something less than the whole) of a target, and/or onto a substrate in other ways. In some embodiments, the radiation may be directed by the radiation source onto the target in a time varying manner. For example, the radiation may be rastered over a target (e.g., by moving the target under the radiation) such that different portions of the target are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a target, comparison of one portion of a target to another and/or to other targets (e.g., in other layers), and/or other analysis.

At operation 1204, a detection signal is generated with a sensor. In some embodiments, the sensor is the same as or similar to detector 4 and/or processor PRO shown in FIG. 3 and described above. In some embodiments, operation 1204 comprises detecting reflected radiation from one or more diffraction grating targets. Detecting reflected radiation comprises detecting one or more phase and/or amplitude (intensity) shifts in reflected radiation from one or more geometric features of the target(s). The one or more phase and/or amplitude shifts correspond to one or more dimensions of a target. For example, the phase and/or amplitude of reflected radiation from one side of a target is different relative to the phase and/or amplitude of reflected radiation from another side of the target.

Detecting the one or more phase and/or amplitude (intensity) shifts in the reflected radiation from the target comprises measuring local phase shifts (e.g., local phase deltas) and/or amplitude variations that correspond to different portions of a target. For example, the reflected radiation from a specific area of a target may comprise a sinusoidal waveform having a certain phase and/or amplitude. The reflected radiation from a different area of the target (or a target in a different layer) may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

In some embodiments, operation 1204 comprises generating a metrology signal based on the detected reflected radiation from diffraction grating target(s), as described above. The metrology signal is generated by a sensor (such as detector 4 in FIG. 3, a camera, and/or other sensors) based on radiation received by the sensor. The metrology signal comprises measurement information pertaining to the target(s). For example, the metrology signal may be an overlay and/or alignment signal comprising overlay and/or alignment measurement information, and/or other metrology signals. The measurement information (e.g., an overlay value, an alignment value, and/or other information) may be determined using principles of interferometry and/or other principles.

The metrology signal comprises an electronic signal that represents and/or otherwise corresponds to the radiation reflected from the target(s). The metrology signal may indicate a metrology value associated with a diffraction grating target, for example, and/or other information. Generating the metrology signal comprises sensing the reflected radiation and converting the sensed reflected radiation into the electronic signal. In some embodiments, generating the metrology signal comprises sensing different portions of the reflected radiation from different areas and/or different geometries of the target, and/or multiple targets, and combining the different portions of the reflected radiation to form the metrology signal. This may include generating and/or analyzing one or more images of a target, using the radiation described herein. This sensing and converting may be performed by components similar to and/or the same as detector 4 and/or processors PRO shown in FIG. 3, and/or other components.

At operation 1206, at least one reflective surface is formed on a body of an optical system adjacent to a recess within the body to create an air gap for total internal reflection of incident radiation on the reflective surface toward a first target or toward the sensor. In some embodiments, the at least one reflective surface is the same as or similar to reflective surface(s) 702 shown in FIG. 7 and described above. At operation 1208, the incident radiation is transmitted through the body, with at least one transmissive surface formed on the body, toward a second target or toward the sensor. In some embodiments, the at least one transmissive surface is the same as or similar to transmissive surface(s) 704 shown in FIG. 7 and described above. The transmissive and reflective surfaces are configured to reduce or eliminate an offset of an incident radiation beam, and/or decrease a risk of parallel plate ghosts compared to prior alignment and/or overlay systems. In some embodiments, the first and second targets comprise different areas of a same target structure on a wafer, two different target structures on the wafer, or two different target structures on two different wafers.

In some embodiments, the at least one reflective surface comprises first and second reflective surfaces arranged in opposite quadrants of a first internal surface of the body. In some embodiments, the at least one transmissive surface comprises first and second transmissive surfaces arranged in two remaining quadrants of the first internal surface. In some embodiments, operation 1206 comprises reflecting, with the first and second reflective surfaces, two quadrants of incident radiation from a radiation source toward the first target. In some embodiments, operation 1208 comprises, with the first and second transmissive surfaces, transmitting the incident radiation from two remaining quadrants of radiation from the radiation source through the body toward the second target, and transmitting radiation reflected from the first target toward the sensor.

In some embodiments, four additional reflective surfaces are arranged in alternating quadrants of a second internal surface of the body, with four additional transmissive surfaces arranged in four remaining quadrants of the second internal surface. In some embodiments, operation 1206 comprises reflecting, with the four additional reflective surfaces, radiation reflected from the second target toward the sensor. In some embodiments, operation 1208 comprises, with the four additional transmissive surfaces, transmitting the incident radiation from the two remaining quadrants of radiation from the radiation source through the body toward the second target, and transmitting radiation reflected from the first target toward the sensor.

In some embodiments, the body comprises three separate portions coupled together to form a unitary structure. The three portions comprise a first portion formed from a transparent material. The first portion is configured to transmit the incident radiation from the radiation source and the reflected radiation from the first target to the first internal surface of the body. The three portions comprise a third portion formed from the transparent material. The third portion is configured to transmit the incident radiation from the radiation source to the second target, and transmit the reflected radiation from the second target to the second internal surface of the body. The three portions comprise a second portion positioned between the first portion and the third portion. The second portion comprises the first and second internal surfaces on opposite sides of the second portion. In some embodiments, operations 1206 and/or 1208 may include forming the first and second reflective surfaces and the four additional reflective surfaces by etching recesses in the first and second internal surfaces respectively, to form air gaps in the body when the three separate portions are coupled together.

In some embodiments, method 1200 includes determining overlay and/or alignment. Overlay and/or alignment are determined based on reflected diffracted radiation from a diffraction grating target and/or other information. In some embodiments, overlay and/or alignment determination is performed by a detector the same as or similar to detector 4 and processor PRO shown in FIG. 3 and described above.

In some embodiments, method 1200 comprises determining an adjustment for a semiconductor device manufacturing process. In some embodiments, method 1200 includes determining one or more semiconductor device manufacturing process parameters. The one or more semiconductor device manufacturing process parameters may be determined based on one or more detected phase and/or amplitude variations, an overlay and/or alignment value indicated by the metrology signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1200 includes determining a process adjustment based on the one or more determined semiconductor device manufacturing process parameters, adjusting a semiconductor device manufacturing apparatus based on the determined adjustment, and/or other operations. For example, if a determined metrology measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1200), for example. In some embodiments, method 1200 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 13 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, all or some of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses. In the following, further features, characteristics, and exemplary technical solutions of the present disclosure will be described in terms of clauses that may be optionally claimed in any combination:
1. An optical system comprising: a body having at least one transmissive surface and at least one reflective surface for radiation incident on different sides of the body, wherein: the at least one reflective surface on the body is adjacent to a recess within the body that creates an air gap for total internal reflection of radiation incident on the reflective surface toward a first target or toward a sensor; and the at least one transmissive surface on the body is configured to transmit incident radiation through the body toward a second target or toward the sensor.
2. The system of clause 1, wherein the at least one reflective surface comprises first and second reflective surfaces arranged in opposite quadrants of a first internal surface of the body, and wherein the at least one transmissive surface comprises first and second transmissive surfaces arranged in two remaining quadrants of the first internal surface.
3. The system of any previous clause, wherein: the first and second reflective surfaces are configured to reflect two quadrants of incident radiation from a radiation source toward the first target, and the first and second transmissive surfaces are configured to (1) transmit the incident radiation from two remaining quadrants of radiation from the radiation source through the body toward the second target, and (2) transmit radiation reflected from the first target toward the sensor.
4. The system of any previous clause, wherein four additional reflective surfaces are arranged in alternating quadrants of a second internal surface of the body, with four additional transmissive surfaces arranged in four remaining quadrants of the second internal surface.
5. The system of any previous clause, wherein: the four additional reflective surfaces are configured to reflect radiation reflected from the second target toward the sensor, and the four additional transmissive surfaces are configured to (3) transmit the incident radiation from the two remaining quadrants of radiation from the radiation source through the body toward the second target, and (4) transmit radiation reflected from the first target toward the sensor.
6. The system of any previous clause, wherein the body comprises three separate portions coupled together to form a unitary structure.
7. The system of any previous clause, wherein the three portions comprise a first portion formed from a transparent material, the first portion configured to transmit the incident radiation from the radiation source and the reflected radiation from the first target to the first internal surface of the body.
8. The system of any previous clause, wherein the three portions further comprise a third portion formed from the transparent material, the third portion configured to transmit the incident radiation from the radiation source to the second target, and transmit the reflected radiation from the second target to the second internal surface of the body.
9. The system of any previous clause, wherein the three portions further comprise a second portion positioned between the first portion and the third portion, the second portion comprising the first and second internal surfaces on opposite sides of the second portion.
10. The system of any previous clause, wherein the first and second reflective surfaces and the four additional reflective surfaces are formed by etching recesses in the first and second internal surfaces respectively, to form air gaps in the body when the three separate portions are coupled together.
11. The system of any previous clause, wherein the second portion has a trapezoidal prism shape.
12. The system of any previous clause, wherein the optical system comprises a double quad mirror.
13. The system of any previous clause, wherein the body comprises a transmissive optic cube.
14. The system of any previous clause, wherein the optical systems forms a portion of an alignment and/or an overlay metrology system.
15. The system of any previous clause, wherein the alignment and/or overlay metrology system comprises a radiation source configured to generate the incident radiation, and the sensor, the sensor configured to receive radiation from the first and/or second targets and generate a detection signal.
16. An alignment and/or overlay metrology system comprising: a radiation source configured to generate incident radiation; a sensor configured to generate a detection signal; and a body having at least one transmissive surface and at least one reflective surface for radiation incident on different sides of the body, wherein: the at least one reflective surface on the body is adjacent to a recess within the body that creates an air gap for total internal reflection of radiation incident on the reflective surface toward a first target or toward a sensor; and the at least one transmissive surface on the body is configured to transmit incident radiation through the body toward a second target or toward the sensor.
17. The system of clause 16, wherein the at least one reflective surface comprises first and second reflective surfaces arranged in opposite quadrants of a first internal surface of the body, and wherein the at least one transmissive surface comprises first and second transmissive surfaces arranged in two remaining quadrants of the first internal surface.
18. The system of any previous clause, wherein: the first and second reflective surfaces are configured to reflect two quadrants of incident radiation from a radiation source toward the first target, and the first and second transmissive surfaces are configured to (1) transmit the incident radiation from two remaining quadrants of radiation from the radiation source through the body toward the second target, and (2) transmit radiation reflected from the first target toward the sensor.
19. The system of any previous clause, wherein four additional reflective surfaces are arranged in alternating quadrants of a second internal surface of the body, with four additional transmissive surfaces arranged in four remaining quadrants of the second internal surface.
20. The system of any previous clause, wherein: the four additional reflective surfaces are configured to reflect radiation reflected from the second target toward the sensor, and the four additional transmissive surfaces are configured to (3) transmit the incident radiation from the two remaining quadrants of radiation from the radiation source through the body toward the second target, and (4) transmit radiation reflected from the first target toward the sensor.
21. The system of any previous clause, wherein the body comprises three separate portions coupled together to form a unitary structure, and wherein the three portions comprise: a first portion formed from a transparent material, the first portion configured to transmit the incident radiation from the radiation source and the reflected radiation from the first target to the first internal surface of the body; a third portion formed from the transparent material, the third portion configured to transmit the incident radiation from the radiation source to the second target, and transmit the reflected radiation from the second target to the second internal surface of the body; and a second portion positioned between the first portion and the third portion, the second portion comprising the first and second internal surfaces on opposite sides of the second portion.
22. The system of any previous clause, wherein the first and second reflective surfaces and the four additional reflective surfaces are formed by etching recesses in the first and second internal surfaces respectively, to form air gaps in the body when the three separate portions are coupled together.
23. The system of any previous clause, wherein the alignment and/or overlay detection metrology system is configured for a semiconductor wafer, and is used in a semiconductor manufacturing process.
24. The system of any previous clause, wherein the first and second targets comprise different areas of a same target structure on a wafer, two different target structures on the wafer, or two different target structures on two different wafers.
25. The system of any previous clause, wherein the transmissive and reflective surfaces are configured to reduce or eliminate an offset of an incident radiation beam, and/or decrease a risk of parallel plate ghosts compared to prior alignment and/or overlay systems.
26. An alignment and/or overlay metrology method, comprising: generating incident radiation with a radiation source; generating a detection signal with a sensor; forming at least one reflective surface on a body adjacent to a recess within the body to create an air gap for total internal reflection of incident radiation on the reflective surface toward a first target or toward the sensor; and transmitting, with at least one transmissive surface formed on the body, the incident radiation through the body toward a second target or toward the sensor.
27. The method of clause 26, wherein the at least one reflective surface comprises first and second reflective surfaces arranged in opposite quadrants of a first internal surface of the body, and wherein the at least one transmissive surface comprises first and second transmissive surfaces arranged in two remaining quadrants of the first internal surface.
28. The method of any previous clause, further comprising: reflecting, with the first and second reflective surfaces, two quadrants of incident radiation from a radiation source toward the first target, and with the first and second transmissive surfaces, transmitting the incident radiation from two remaining quadrants of radiation from the radiation source through the body toward the second target, and transmitting radiation reflected from the first target toward the sensor.
29. The method of any previous clause, wherein four additional reflective surfaces are arranged in alternating quadrants of a second internal surface of the body, with four additional transmissive surfaces arranged in four remaining quadrants of the second internal surface.
30. The method of any previous clause, further comprising: reflecting, with the four additional reflective surfaces, radiation reflected from the second target toward the sensor, and with the four additional transmissive surfaces, transmitting the incident radiation from the two remaining quadrants of radiation from the radiation source through the body toward the second target, and transmitting radiation reflected from the first target toward the sensor.
31. The method of any previous clause, wherein the body comprises three separate portions coupled together to form a unitary structure, and wherein the three portions comprise: a first portion formed from a transparent material, the first portion configured to transmit the incident radiation from the radiation source and the reflected radiation from the first target to the first internal surface of the body; a third portion formed from the transparent material, the third portion configured to transmit the incident radiation from the radiation source to the second target, and transmit the reflected radiation from the second target to the second internal surface of the body; and a second portion positioned between the first portion and the third portion, the second portion comprising the first and second internal surfaces on opposite sides of the second portion.
32. The method of any previous clause, further comprising forming the first and second reflective surfaces and the four additional reflective surfaces by etching recesses in the first and second internal surfaces respectively, to form air gaps in the body when the three separate portions are coupled together.
33. The method of any previous clause, wherein the alignment and/or overlay detection metrology method is configured for a semiconductor wafer, and is used in a semiconductor manufacturing process.
34. The method of any previous clause, wherein the first and second targets comprise different areas of a same target structure on a wafer, two different target structures on the wafer, or two different target structures on two different wafers.
35. The method of any previous clause, wherein the transmissive and reflective surfaces are configured to reduce or eliminate an offset of an incident radiation beam, and/or decrease a risk of parallel plate ghosts compared to prior alignment and/or overlay systems.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. An optical system comprising:
a body having at least one transmissive surface and at least one reflective surface for radiation incident on different sides of the body, wherein:
the at least one reflective surface on the body is adjacent to a recess, within the body, that creates an air gap for total internal reflection of radiation incident on the at least one reflective surface toward a first target or toward a sensor; and
the at least one transmissive surface on the body is configured to transmit incident radiation through the body toward a second target or toward the sensor.

2. The system of claim 1, wherein the at least one reflective surface comprises first and second reflective surfaces arranged in opposite quadrants of a first internal surface of the body, and wherein the at least one transmissive surface comprises first and second transmissive surfaces arranged in two remaining quadrants of the first internal surface.

3. The system of claim 2, wherein:
the first and second reflective surfaces are configured to reflect two quadrants of incident radiation from a radiation source toward the first target, and
the first and second transmissive surfaces are configured to (1) transmit the incident radiation from two remaining quadrants of radiation from the radiation source through the body toward the second target, and (2) transmit radiation reflected from the first target toward the sensor.

4. The system of claim 3, wherein four additional reflective surfaces are arranged in alternating quadrants of a second internal surface of the body, with four additional transmissive surfaces arranged in four remaining quadrants of the second internal surface.

5. The system of claim 4, wherein:
the four additional reflective surfaces are configured to reflect radiation reflected from the second target toward the sensor, and
the four additional transmissive surfaces are configured to (3) transmit the incident radiation from the two remaining quadrants of radiation from the radiation source through the body toward the second target, and (4) transmit radiation reflected from the first target toward the sensor.

6. The system of claim 5, wherein the body comprises three separate portions coupled together to form a unitary structure.

7. The system of claim 6, wherein the three portions comprise a first portion formed from transparent material, the first portion configured to transmit the incident radiation from the radiation source and the reflected radiation from the first target to the first internal surface of the body.

8. The system of claim 7, wherein the three portions further comprise a third portion formed from transparent material, the third portion configured to transmit the incident radiation from the radiation source to the second target, and transmit the reflected radiation from the second target to the second internal surface of the body.

9. The system of claim 8, wherein the three portions further comprise a second portion positioned between the first portion and the third portion, the second portion comprising the first and second internal surfaces on opposite sides of the second portion.

10. The system of claim 9, wherein the first and second reflective surfaces and the four additional reflective surfaces are formed by etching recesses in the first and second internal surfaces respectively, to form air gaps in the body when the three separate portions are coupled together.

11. The system of claim 9, wherein the second portion has a trapezoidal prism shape.

12. The system of claim 1, wherein the optical system comprises a double quad mirror.

13. The system of claim 1, wherein the body comprises a transmissive optic cube.

14. The system of any of claim 1, wherein the optical systems forms a portion of an alignment and/or an overlay metrology system.

15. The system of claim 14, wherein the alignment and/or overlay metrology system comprises a radiation source configured to generate the incident radiation, and the sensor, the sensor configured to receive radiation from the first and/or second targets and generate a detection signal.

16. A metrology system comprising:
a radiation source configured to generate incident radiation;
a sensor configured to generate a detection signal; and
a body having at least one transmissive surface and at least one reflective surface for radiation incident on different sides of the body, wherein:
the at least one reflective surface on the body is adjacent to a recess, within the body, that creates an air gap for total internal reflection of radiation incident on the reflective surface toward a first target or toward the sensor; and
the at least one transmissive surface on the body is configured to transmit incident radiation through the body toward a second target or toward the sensor.

17. The system of claim 16, wherein the at least one reflective surface comprises first and second reflective surfaces arranged in opposite quadrants of a first internal surface of the body, and wherein the at least one transmissive surface comprises first and second transmissive surfaces arranged in two remaining quadrants of the first internal surface.

18. A metrology method, comprising:
generating incident radiation with a radiation source;
generating a detection signal with a sensor;
reflecting the incident radiation using at least one reflective surface on a body adjacent to a recess within the body that creates an air gap for total internal reflection of the incident radiation on the at least one reflective surface toward a first target or toward the sensor; and
transmitting, with at least one transmissive surface formed on the body, the incident radiation through the body toward a second target or toward the sensor.

18. The method of claim 18, wherein the at least one reflective surface comprises first and second reflective surfaces arranged in opposite quadrants of a first internal surface of the body, and wherein the at least one transmissive surface comprises first and second transmissive surfaces arranged in two remaining quadrants of the first internal surface.

19. The method of claim 18, further comprising:
reflecting, with the first and second reflective surfaces, two quadrants of incident radiation from a radiation source toward the first target, and
with the first and second transmissive surfaces, transmitting the incident radiation from two remaining quadrants of radiation from the radiation source through the body toward the second target, and transmitting radiation reflected from the first target toward the sensor.

20. The method of claim 18, wherein four additional reflective surfaces are arranged in alternating quadrants of a second internal surface of the body, with four additional transmissive surfaces arranged in four remaining quadrants of the second internal surface.
